(19) United States
(12) Patent Application Publication
(10) Pub. No.: US 2025/0207254 A1
(43) Pub. Date: Jun. 26, 2025

(54) METAL PHOSPHIDE DEPOSITION VIA PHOSPHASILANE REACTANTS AND RELATED STRUCTURES

(71) Applicant: Intel Corporation, Santa Clara, CA (US)

(72) Inventor: Scott Peter Semproni, Fair Lawn, NJ (US)

(21) Appl. No.: 18/396,106

(22) Filed: Dec. 26, 2023

(51) Int. Cl. C23C 16/455; C23C 16/30; H01L 21/285; H01L 23/532; H01L 29/423; H01L 29/45; H01L 29/49; H01L 29/775; H01L 29/786

(52) U.S. Cl. CPC C23C 16/45553; C23C 16/30; H01L 21/28568; H01L 23/53238; H10D 62/83; H10D 64/62; H10D 64/667; H10D 30/43; H10D 30/6735; H10D 30/6757

(57) ABSTRACT

Metal phosphide deposition via phosphoserine reactants and related structures are disclosed. An example method to deposit a metal phosphide layer via atomic layer deposition, the method including applying a first pulse of a metal precursor to a substrate, purging the first pulse, applying a second pulse of a phosphasilane precursor, and purging the second pulse.

### FIELD OF THE DISCLOSURE

This disclosure relates generally to material deposition and, more particularly, to metal phosphide deposition via phosphasilane reactants and related structures.

### BACKGROUND

In many electronic devices, integrated circuit (IC) chips and/or semiconductor dies are connected to larger circuit boards such as motherboards and/or other types of printed circuit boards (PCBs) via a package substrate. Some known IC packages utilize voltage regulators for power delivery applications. In some instances, capacitors and/or other semiconductor components used for such voltage regulators can be included in the package substrate for an IC package.

### BRIEF DESCRIPTION OF THE DRAWINGS

FIG. 1 is a schematic illustration of an atomic layer deposition cycle for depositing metal phosphides implemented in accordance with the teachings of this disclosure.

FIG. 2 is a block diagram of an example process for the deposition of metal phosphides via atomic layer deposition.

FIG. 3 is a cross-sectional view of a base including high aspect ratio trenches and a metal phosphide layer implemented in accordance with the teachings of this disclosure.

FIG. 4 is a cross-sectional schematic view of a first contact of a transistor including a metal phosphide layer implemented in accordance with teachings of this disclosure.

FIG. 5 is a cross-sectional schematic view of a gate all around transistor including a metal phosphide layer implemented in accordance with teachings of this disclosure.

FIG. 6 is a top view of a wafer and dies that may be included in an IC package constructed in accordance with teachings disclosed herein.

FIG. 7 is a cross-sectional side view of an IC device that may be included in an IC package constructed in accordance with teachings disclosed herein.

FIG. 8 is a cross-sectional side view of an IC device assembly that may include an IC package constructed in accordance with teachings disclosed herein.

FIG. 9 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

In recent years, the miniaturization of transistors and related components has caused layers of metal materials, such as those associated with the contacts of transistors and work function metals, to have thicknesses of less than four nanometers (nm). One process that enables the deposition of materials with thicknesses less than 4 nm is atomic layer deposition (ALD). ALD is a type of chemical vapor deposition (CVD) that enables the deposition of materials in single molecule layers via the alternating introduction (e.g., application, etc.) of precursors, also referred to herein as reactants, and the self-limiting surface reactions associated therewith. Because each cycle of precursor deposition deposits a single one-molecule thickness layer of material, thickness control is possible by controlling the number of precursor application cycles. Additionally, because the precursors are typically applied in gaseous form and react with the exposed surfaces in a self-terminating fashion, ALD enables the deposition of layers with uniform thickness regardless of the geometry of the base layer, including base layers with high aspect ratio features (e.g., deep trenches, etc.).

Metal phosphides are an emergent class of material that are suitable for use in applications that include layers of material that are less than 4 nm, such as source/drain (S/D) contacts for n-type metal-oxide-semiconductor (NMOS) transistors and work function metals for gate-all around structures. One prior method of depositing layers of metal phosphides is via physical vapor deposition techniques, such as sputtering deposition. However, prior sputtering deposition techniques for metal phosphides result in layers of non-uniform thickness, particularly those involving surface geometries that include high aspect ratio features. Another, prior method of depositing layers of metal phosphides is chemical vapor deposition via phosphine (PH₃). Because phosphine is pyrophoric and highly toxic, the handling, storage, and application of phosphine can be undesirable. Additionally, many prior CVD processes for depositing metal phosphides include the application of vaporous phosphine at extremely high temperatures and/or the application of phosphine plasma, which can damage adjacent features of the surface geometry. Additionally, many prior CVD processes do not deposit thin films uniformly over complex features, making the use of such CVD processes unsuitable for highly scaled structures such as deep trenches and gate-all-around transistors difficult. Furthermore, the high bond strength (e.g., the bond disassociation energy, etc.) of a hydrogen phosphorus bond (H—P) (e.g., 343 kilojoules (kJ) per mole (mol), etc.) can limit what metal phosphides can be deposited via phosphine precursors.

Examples disclosed herein overcome deficiencies of prior metal phosphide deposition techniques and include operations for depositing metal phosphides via atomic layer deposition using phosphasilane precursors. Example operations disclosed herein include ALD cycles that include the alternating application of phosphasilane precursors and metal-containing precursors, which are also referred to herein as metal precursors. Example phosphasilane precursors disclosed herein include trisilylphosphine (P(SiH₃)₃) and tris(trimethylsilyl)-phosphine (P(SiMe₃)₃). Example metal precursors disclosed herein include metal halides (e.g., metal chlorides, metal fluorides, etc.), metal amides, and metal alkoxides. Examples disclosed herein enable the deposition of layers including a transition metal and a phosphorus atom. Examples disclosed herein enable the deposition of uniform layers including metal phosphides of less than 4 nanometers. An example NMOS contact structure disclosed herein includes a metal phosphide contact liner of less than 4 nanometers. An example gate all round transistor disclosed herein includes a work function layer that includes a metal phosphide contact liner of less than 4 nanometers.

Examples disclosed herein include references to chemical formulas and chemical equations. Generally, chemical formulas are referred to in their empirical forms (e.g., not their molecular form, etc.). Generally, elements in such chemical formulas and chemical equations are referred to herein by their chemical symbols (e.g., phosphorus is referred to herein as “P,” chlorine is referred herein to as “Cl,” Hydrogen is referred to as “H,” etc.). Additionally, alkyl groups are referred to as “R” (e.g., a chemical formula including “R” could include any alkyl group, etc.). Metals are collectively referred to as “M” (e.g., a chemical formula including “M” could include any metal having any suitable oxidation state, etc.). Methyl groups (CH₃) are referred to as “Me.” Ethyl groups (CH₂CH₃) are referred to as “Et.” Butyl groups (C₄H₉) are referred to as “Bu.” Octyl groups (C₈H₁₅) are referred to as “Ot.” Isopropyl groups (C₈H₁₅) are referred to as “iPr.” Amidines (RC(NR)NR₂) and amidinates are referred to as AMDs. Tetramethylethylenediamine ((CH₃)₂NCH₂CH₂N(CH₃)₂) is referred to herein as TMEDA. Acetylacetone (CH₃—C(═O)—CH₂—C(═O)—CH₃) is referred to herein as “acac.” Hexafluoroacetylacetone (CF₃C(O)CH₂C(O)CF₃) is referred to herein as “hfac.” The subscript “n” is used in conjunction with materials where the number of atoms of the element is variable based on the oxidation state of the metal (e.g., WClₙ refers to tungsten(II) chloride (WCl₂), tungsten (III) chloride (WCl₃), tungsten (IV) chloride (WCl₄), etc.) and/or variable based on the nature of the bonded atom (e.g., MClₙ refers to any metal chloride, MFₙ refers to any metal fluoride, M(OR)ₙ refers to any metal alkoxide, M(NR)ₙ refers to any metal amides, etc.).

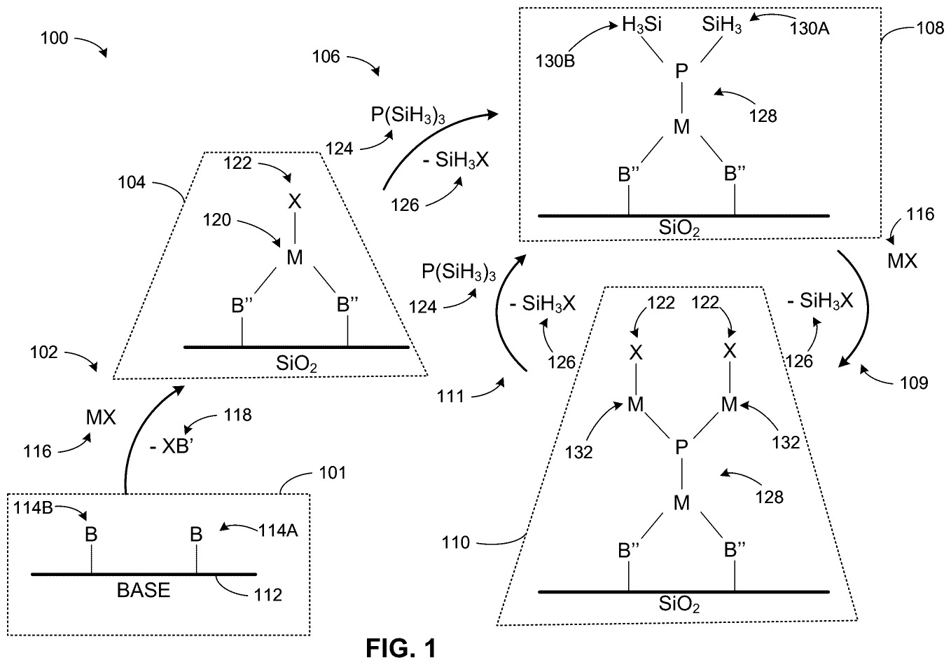

FIG. 1 is a schematic illustration of an example atomic layer deposition (ALD) cycle 100 for depositing metal phosphide layers and/or metal phosphide films implemented in accordance with teachings of this disclosure. In the illustrated example of FIG. 1, the example ALD cycle 100 includes an example first stage 101. In the illustrated example of FIG. 1, an example first precursor pulse 102 is applied to the first stage 101, which causes the formation of an example second stage 104. In the illustrated example of FIG. 1, an example second precursor pulse 106 is applied to the second stage 104, which causes the formation of the third stage 108. In the illustrated example of FIG. 1, an example third precursor pulse 109 is applied to the third stage 108, which causes the formation of the fourth stage 110. In the illustrated example of FIG. 1, the second precursor pulse 106 is applied to the fourth stage 110, which causes the formation of a stage similar to the third stage 108. In the illustrated example of FIG. 1, “X” refers to one of an alkoxy group (OR), an amine group (NR₂), chlorine (Cl), fluorine (F), and/or other halides (e.g., bromine, iodine, etc.).

The first stage 101 includes an example base material 112, an example first reactive site 114A, and an example second reactive site 114B. In the illustrated example of FIG. 1, the base material 112 is illustrated as “BASE” and the reactive sites 114A, 114B are illustrated as “B.” In some examples, the base material 112 is silicon dioxide (e.g., silica, SiO₂, etc.). In some such examples, the base material 112 is passivation layer of a semiconductor, a gate dielectric, etc. In some examples, the first stage 101 can is a component of an integrated circuit (e.g., a die, a package substrate, etc.) and/or another apparatus that includes extremely small components. In the illustrated example of FIG. 1, the base material 112 includes reactive sites, including the first reactive site 114A and the second reactive site 114B. In some examples, if the base material is silicon dioxide, the reactive sites 114A, 114B are hydroxyls (OH⁻) that are bonded to the surface of the base material 112. In some examples, the reactive sites 114A, 114B are naturally occurring (e.g., occurring on the base material, arising from a reaction of the base material and the ambient atmosphere, etc.) and/or caused by a previous reaction (e.g., a previous application of a precursor, etc.).

The first precursor pulse 102 is applied to the first stage 101 to form the second stage 104. In the illustrated example of FIG. 1, the first precursor pulse 102 includes an example first precursor 116 (e.g., a metal precursor, etc.) and an example first byproduct 118. The first precursor pulse 102 is represented via Equation (1):

$$MX + 2 B \to {MXB}_{2}^{″} + {AXB}^{′} \qquad ( 1 )$$

where “MX” is the first precursor 116, “2B” is the material as associated with the reactive sites 114A, 114B, “MXB₂” is an example temporarily deposited material 120 disposed on the base material 112, “XB′” is the first byproduct 118, and “A” is the stoichiometric number of the first byproduct 118. The value of A depends on the first precursor 116 (e.g., the number of X atoms, etc.). The identities of B′ and B″ depend on the material of the reactive sites 114A, 114B. In the illustrated example of FIG. 1, B′ is the portion of the material of the reactive sites 114A, 114B that is associated with the first byproduct 118. For example, if the reactive sites 114A, 114B are hydroxyls, the B′ is a hydrogen atom. In the illustrated example of FIG. 1, B″ is the portion of the material of the reactive sites 114A, 114B that forms a bond with the metal atom of the first precursor 116. For example, if the reactive sites 114A, 114B are hydroxyls, the B″ is an oxygen atom. The metal of the first precursor 116 is the elemental metal included in the metal phosphide that is to be deposited on the base material 112. The first precursor 116 can include a metal halide (e.g., a metal chloride, a metal fluoride, a metal bromide, a metal iodide, etc.), a metal amide, and/or a metal alkoxide. For example, if a layer of tungsten phosphide is to be formed on the base material 112, the first precursor 116 can be a tungsten chloride (WClₙ), a tungsten fluoride (WFₙ), a tungsten bromide (WBrₙ), a tungsten iodide (WIₙ), a tungsten amide complex (W(NR₂)ₙ) (e.g., W₂(NMe)₆, etc.), and/or a tungsten alkoxide (W(OR)ₙ) (e.g., W₄(OR)₁₆, etc.). For example, if a layer of copper phosphide is to be formed on the base material 112, the first precursor 116 can be a copper fluoride (CuFₙ) (e.g., etc.) copper(I) fluoride, copper(II) fluoride, etc.), a copper chloride (CuClₙ) (e.g., copper(I) chloride, copper(II) chloride, etc.), a copper bromide (CuBrₙ), a copper iodide (CuIₙ), a copper amide (Cu(NR₂)ₙ), and/or a copper alkoxide (Cu(OR)ₙ) (e.g., a copper(I) t-butoxide, etc.)). The first precursor 116 can be applied to the first stage 101 as a vapor (e.g., a gas, etc.). In some examples, to facilitate the reaction of the first precursor 116 and the reactive sites 114A, 114B, the base material 112 can be heated, and/or the first precursor 116 can be applied at an elevated temperature.

While the ALD cycle 100 is applied to a base layer of silicon oxide (e.g., the base material 112, etc.) in the illustrated example of FIG. 1, in other examples the ALD cycle 100 can be applied to any base that has a favorable reaction with the first precursor 116 (e.g., the chemical equilibrium facilitates the formation of the second stage 104, etc.). For example, the base material 112 can include silicon nitride, metal nitrides, silicon carbide, crystalline silicon, silicon—germanium, metal oxides, metals (e.g., metallic tungsten, metallic copper, etc.). In some examples, a surface treatment can be applied to the base material 112 to ensure proper nucleation of the deposited layers of metal phosphide. In some examples, the base material 112 can be cleaned prior to the deposited layers of metal phosphide . . . . While the base material 112 is depicted as a flat surface, it should be appreciated that the atomic layer deposition cycle 100 can deposit a metal phosphide on any suitable surface geometry, including surface geometries that include high aspect ratio features (e.g., trenches, etc.).

During the reaction of the first precursor 116 and the reactive sites 114A, 114B, the first byproduct 118 is formed. The chemical formula of the first byproduct 118 depends on the chemical formula of the first precursor 116 and/or the material of the reactive sites 114A, 114B. For example, if the first precursor 116 is tungsten chloride and the reactive sites 114A, 114B are hydroxyl, the first byproduct is hydrogen chloride (HCl). For example, if the first precursor 116 is copper fluoride and the reactive sites 114A, 114B are hydroxyl, the first byproduct is hydrogen fluoride (HF). In some examples, depending on the chemical formula of the first precursor 116, the reactive sites 114A, 114B, and the temperature of the application of the first precursor pulse 102, the first byproduct 118 can be in any suitable state (e.g., a gas, a liquid, a solid, etc.). In some examples, the first byproduct 118 can be purged/evacuated via an application of a purging gas (e.g., a noble gas, nitrogen gas (e.g., N₂, etc.)).

The second stage 104 is formed via the reaction of the first precursor 116 and the reactive sites 114A, 114B and the purging of the first byproduct 118. In the illustrated example of FIG. 1, the second stage 104 includes the temporarily deposited material 120, which includes an example third reactive site 122. The temporarily deposited material 120 includes the metal of the first precursor 116 and one of chloride, fluoride, an amide, and/or an alkyl, which is the third reactive site 122.

The second precursor pulse 106 is applied to the second stage 104 to form the third stage 108. In the illustrated example of FIG. 1, the first precursor pulse 102 includes an example second precursor 124 (e.g., a phosphasilane precursor, etc.) and an example second byproduct 126. The second precursor pulse 106 is represented via Equation (2):

$$2 MX + {P ( {SiH}_{3} )}_{3} \to {M}_{2} P - SiH 3 + 2 {SiH}_{3} X \qquad ( 2 )$$

where “MX” is the material of the reactive site 122, “P(SiH₃)₃” is the second precursor material 124, “SiH₃X” is the second byproduct 126, “MP” is an example deposited metal phosphide 128, which varies based on the first precursor 116. While the illustrated example of FIG. 1 and Equation (2) depict the second precursor 124 as trisilylphosphine, in other examples, the second precursor 124 can be tris(trimethylsilyl)-phosphine and/or any other suitable phosphasilane (e.g., P(SiH₁R₂)₃, P(SiH₂R₁)₃, P(SiR₃)₃, etc.). In the illustrated example of FIG. 1, the second byproduct 126 is a silanide group coupled to the non-metal portion of the first precursor 116 (e.g., chlorine, fluorine, an amide, an alkyl, etc.).

The third stage 108 is formed via the reaction of the second precursor 124 and the third reactive site 122 and the purging of the second byproduct 126. In the illustrated example of FIG. 1, the third stage 108 includes a deposited layer of metal phosphide 128, an example fourth reactive site 130A, and an example fifth reactive site 130B. In the illustrated example of FIG. 1, the deposited layer of metal phosphide 128 is one molecule thick. The deposited layer of metal phosphide 128 includes an example metal (e.g., a transition metal, etc.) and a phosphorus. In the illustrated example of FIG. 1, the reactive sites 130A, 130B are silanides (SiH₃). In other examples, if the second precursor 124 is tris(trimethylsilyl)-phosphine, the reactive sites 130A, 130B are trimethysilanes (SiMe₃).

The third precursor pulse 109 is similar to the first precursor pulse 102. Particularly, the third precursor pulse 109 includes the first precursor 116. In the illustrated example of FIG. 1, the reaction between the first precursor 116 and the reactive sites 130A, 130B generates the second byproduct 126. After the third precursor pulse 109, the second byproduct 126 can be purged/evacuated via an application of a purging gas (e.g., a noble gas, nitrogen gas (N₂), etc.). The third precursor pulse 109 is represented via Equation (3):

$$M 2 P - {SiH}_{3} + M {X}_{2} \to M 2 P M - X + {SiH}_{3} X \qquad ( 3 )$$

where “MX₂” is the first precursor 116, “SiH₃” is the material of the reactive sites 130A, 130B, “SiH₃X” is the second byproduct 126, “MP” is the example deposited metal phosphide 128, and M-X is the third reactive site 122.

The fourth stage 110 is formed via the reaction of the first precursor 116 and the reactive sites 130A, 130B and the purging of the second byproduct 126. The fourth stage 110 is similar to the second stage 104. Particularly, the fourth stage 110 has two of the reactive sites 122 of the second stage 104. In the illustrated example of FIG. 1, the fourth stage 110 includes example metal atoms 132. The metal atoms 132 are the metal from the first precursor 116 applied during the application of the third precursor pulse 109. The metal atoms 132 form part of the subsequent layer of metal phosphide deposited on the metal phosphide 128.

The fourth precursor pulse 111 is similar to the second precursor pulse 106. Particularly, the third precursor pulse 109 includes the second precursor 124 and the reaction between the second precursor 124 and the reactive sites 122 generates the second byproduct 126. The application of the second precursor 124 to the third stage 108 causes a phosphorus atom to replace the “X” (e.g., one or chlorine, fluorine, an amide group, an alkyl group, etc.) of the reactive sites 122, which forms another layer of metal phosphide on the deposited layer of the metal phosphide 128. After the fourth precursor pulse 111, the second byproduct 126 can be purged/evacuated via an application of a purging gas (e.g., a noble gas, nitrogen gas (N₂), etc.). The fourth precursor pulse 111 is represented via Equation (2).

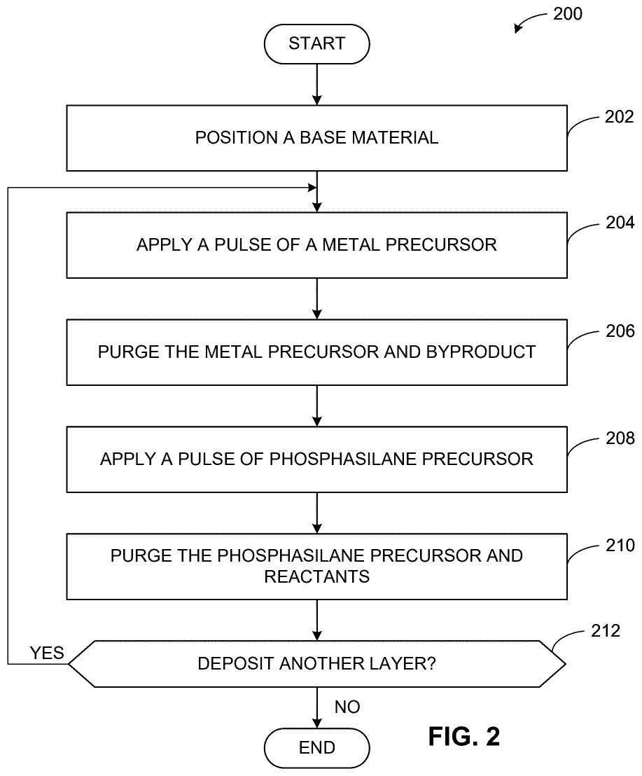

After the application of the fourth precursor pulse 111, a stage similar to the third stage 108 is formed. Particularly, the exposed layer of the formed stage (e.g., the reactive sites of the formed stage, etc.) includes silanides. To deposit another layer of metal phosphide, another pulse including the first precursor 116 can be applied, which causes the formation of a stage similar to the fourth stage 110 (e.g., having reactive sites including one or chlorine, fluorine, an amide group, an alkyl group, etc.). Pulses including the first precursor 116 and the second precursor 124 can be alternatively applied (e.g., as half cycles of the ALD cycle 100, etc.) to continuously deposit one molecule thick layers of metal phosphide on the base material 112. The structure of the layers of the deposited metal phosphide depends on the oxidation state of the metal associated with the first precursor 116 (e.g., the number of bonds formed by the metal atom 120 depends on the oxidation state of the metal atom, etc.). Accordingly, the ALD cycle 100 of FIG. 1 can be used to deposit metal phosphide layers having a controlled uniform thickness based on the number of times the third precursor pulse 109 and the fourth precursor pulse 111 are repeated. Example operations for depositing a layer of a desired thickness are described below in conjunction with FIG. 2.

Generally, the comparative bond energy of MX bonds, SiX bonds, MP bonds, and SiP bonds causes the chemical reaction of Equation (2) to be biased toward the right (e.g., the equilibrium tends towards the metal phosphide 128 and the generation of the second byproduct 126, etc.). That is, the bond energy of the bonds of the metal phosphide 128 and the second byproduct 126 tends to be higher than the bond energy of the bonds of the second precursor 124 and the bond of the third reactive site 122. As used herein, the difference in bond energy between the left and right sides of a chemical reaction is referred to as “favorability.” Reactions that are comparatively more favorable have higher bond energy on the right side of the equation than the left side of the equation, which is represented by a greater negative number (e.g., −5 KJ/mol reaction is less favorable than a −25 KJ/mol reaction, etc.). Reactions that are “unfavorable” are those with a higher bond energy on the left side of the chemical formula (e.g., a 5 KJ/mol reaction is unfavorable, etc.). In the context of ALD half-cycles, if a precursor pulse is unfavorable, the precursor will not cause the formation of a sequential stage.

The use of phosphasilane precursors, such as the second precursor 124, enables the deposition of metal phosphide via chemical reactions that were unfavorable using previous phosphine (PH₃) based precursors. For example, a reaction for the deposition of the tungsten phosphide (WP) is depicted in Equation (4):

$${WCl}_{5} + {P ( {SiH}_{3} )}_{3} \to WP + {SiH}_{3} Cl \qquad ( 4 )$$

where “WCl₅” is the first precursor 116 (e.g., tungsten (V) chloride, etc.), “P(SiH₃)₃” is the second precursor material 124 (e.g., trisilylphosphine, etc.), “SiH₃Cl is the second byproduct 126 (e.g., chlorosilane, etc.), “WP” is an example deposited metal phosphide 128 (e.g., tungsten phosphide, etc.). During the deposition of tungsten phosphide via the reaction of Equation (4), alternating pulses of a tungsten(V) chloride precursor and a trisilylphosphine precursor are applied via the ALD cycle 100. During the metal precursor pulse, molecules of tungsten(V) chloride precursor react with corresponding the available silanides (SiH₃) reactive sites of the preceding stage, forms tungsten-phosphorus bonds, and generates chlorosilane as a byproduct. During the phosphasilane pulse, molecules of trisilylphosphine precursor react with corresponding the available tungsten-chloride reactive sites of the preceding stage and generates chlorosilane as a byproduct. In Equation (4), a W—Cl bond and a Si—P bond are exchanged for a W—P bonds and a Si—Cl bond, respectively, from left to right. The favorability of this reaction is represented in Table 1 below:

TABLE 1
Favorability of Tungsten Phosphide Deposition via
Phosphasilane and Tungsten Chlorine Precursors

| Left Side | Bond Dissociation | Bond Dissociation | Right Side |
|---|---|---|---|
| Bonds | Energy | Energy | Bonds |
| W—Cl | 423 kJ/mol | 305 kJ/mol | W—P |
| Si—P | 293 kJ/mol | 456 kJ/mol | Si—Cl |
| Total Bond | 716 kJ/mol | 761 kJ/mol | |
| Disassociation | | | |
| Energy: | | | |
| | | −45 kJ/mol | :Favorability |

As illustrated in Table 1, the deposition of tungsten phosphide via a tungsten chlorine precursor (e.g., the first precursor 116, etc.) and a phosphasilane precursor (e.g., the second precursor 124, etc.) is favorable. As such, the ALD cycle 100 of FIG. 1 can be used for the deposition of tungsten phosphide.

Consider the favorability of a similar reaction for the deposition of tungsten phosphide via prior ALD process using a phosphine gas precursor, which is expressed below in Equation (5):

$${WCl}_{5} + {PH}_{3} \to WP + HCl \qquad ( 5 )$$

where “WCl₅” is a first precursor material (e.g., tungsten (V) chloride, etc.), “PH₃” is a second precursor material (e.g., phosphine, etc.), “HCl” is a byproduct (e.g., hydrogen chloride, etc.), “WP” is the deposited metal phosphide (e.g., tungsten phosphide, etc.). In Equation (5), a W—Cl bond and a P—H bond are exchanged for a W—P bonds and a H—Cl bond, respectively, from left to right. The favorability of this reaction is represented in Table 2 below:

TABLE 2
Favorability of Tungsten Phosphide Deposition
via Phosphine and Tungsten Chlorine Precursors

| Left Side | Bond Dissociation | Bond Dissociation | Right Side |
|---|---|---|---|
| Bonds | Energy | Energy | Bonds |
| W—CL | 423 kJ/mol | 305 kJ/mol | W—P |
| H—P | 343 kJ/mol | 431 kJ/mol | H—Cl |
| Total Bond | 766 kJ/mol | 736 kJ/mol | |
| Disassociation | | | |
| Energy: | | | |
| | | 30 kJ/mol | :Favorability |

As illustrated in Table 2, the deposition of tungsten phosphide via a tungsten chlorine precursor and a phosphine precursor is unfavorable (e.g., the net bond energy is positive, etc.). As such, prior ALD processes including phosphine precursors cannot be used to deposit tungsten phosphine. Accordingly, use of the ALD cycle 100 of FIG. 1 enables the deposition of metal phosphides, such as tungsten phosphide, that prior ALD processes are unable to deposit without phosphine plasma, which could damage the base material (e.g., the base material 112, etc.). Due to the comparatively lower bond strength of Si—P bond when compared to H—P bonds, the ALD cycle 100 enables the deposition of metal phosphides including transition metals (e.g., copper Cu), tungsten (W), titanium (Ti), zirconium (Zr), iron (Fe), hafnium (Hf), tantalum (Ta), niobium (Nb), vanadium (V), cobalt (Co), nickel (Ni), molybdenum (Mo), ruthenium (Ru), scandium (Sc), yttrium (Y), lanthanum (La), lutetium (Lu), etc.).

The example atomic layer deposition cycle 100 can be used in conjunction with a variety of precursors (e.g., applied via the precursor pulses 102, 106, etc.), which can cause the formation of corresponding metal phosphide layers. An example table depicting example cycles representative of the ALD cycle 100 is depicted below in Table 1:

TABLE 3
Precursors for Atomic Deposition Cycles
Representation of the ALD Cycle 100

| | Second | Deposited Metal |
|---|---|---|
| First Precursor | Precursor | Phosphide Layer |
| ScCl₃ | P(SiH₃)₃ | ScP |
| ScCl₃ | P(SiMe₃)₃ | ScP |
| ScF₃ | P(SiH₃)₃ | ScP |
| ScF₃ | P(SiMe₃)₃ | ScP |
| TiClₙ | P(SiH₃)₃ | TiP |
| TiClₙ | P(SiMe₃)₃ | TiP |
| TiFₙ | P(SiH₃)₃ | TiP |
| TiFₙ | P(SiMe₃)₃ | TiP |
| TiI₄ | P(SiH₃)₃ | TiP |
| TiI₄ | P(SiMe₃)₃ | TiP |
| TiBr₄ | P(SiH₃)₃ | TiP |
| TiBr₄ | P(SiMe₃)₃ | TiP |
| Ti(OMe)₄ | P(SiH₃)₃ | TiP |
| Ti(OMe)₄ | P(SiMe₃)₃ | TiP |
| Ti(OiPr)₄ | P(SiH₃)₃ | TiP |
| Ti(OiPr)₄ | P(SiMe₃)₃ | TiP |
| WCl₅ | P(SiH₃)₃ | WP |
| WCl₅ | P(SiMe₃)₃ | WP |
| WCl₆ | P(SiH₃)₃ | WP |
| WCl₆ | P(SiMe₃)₃ | WP |
| WF₆ | P(SiH₃)₃ | WP |
| WF₆ | P(SiMe₃)₃ | WP |
| WOCl₄ | P(SiH₃)₃ | WP |
| WOCl₄ | P(SiMe₃)₃ | WP |
| W₂(NMe₂)₆ | P(SiH₃)₃ | WP |
| W₂(NMe₂)₆ | P(SiMe₃)₃ | WP |
| YCl₃ | P(SiH₃)₃ | YP |
| YCl₃ | P(SiMe₃)₃ | YP |
| YF₃ | P(SiH₃)₃ | YP |
| YF₃ | P(SiMe₃)₃ | YP |
| LaCl₃ | P(SiH₃)₃ | LaP |
| LaCl₃ | P(SiMe₃)₃ | LaP |
| La(IPrAMD)₃ | P(SiH₃)₃ | LaP |
| La(IPrAMD)₃ | P(SiMe₃)₃ | LaP |
| LuCl₃ | P(SiH₃)₃ | LuP |
| LuCl₃ | P(SiMe₃)₃ | LuP |
| ZrCl₄ | P(SiH₃)₃ | ZrP |
| ZrCl₄ | P(SiMe₃)₃ | ZrP |
| ZrBr₄ | P(SiH₃)₃ | ZrP |
| ZrBr₄ | P(SiMe₃)₃ | ZrP |
| ZrI₄ | P(SiH₃)₃ | ZrP |
| ZrI₄ | P(SiMe₃)₃ | ZrP |
| Zr(NMeEt)₄ | P(SiH₃)₃ | ZrP |
| Zr(NMeEt)₄ | P(SiMe₃)₃ | ZrP |
| Zr(NEt₂)₄ | P(SiH₃)₃ | ZrP |
| Zr(NEt₂)₄ | P(SiMe₃)₃ | ZrP |
| HfCl₄ | P(SiH₃)₃ | HfP |
| HfCl₄ | P(SiMe₃)₃ | HfP |
| HfF₄ | P(SiH₃)₃ | HfP |
| HfF₄ | P(SiMe₃)₃ | HfP |
| HfBr₄ | P(SiH₃)₃ | HfP |
| HfBr₄ | P(SiMe₃)₃ | HfP |
| HfI₄ | P(SiH₃)₃ | HfP |
| HfI₄ | P(SiMe₃)₃ | HfP |
| Hf(NMeEt)₄ | P(SiH₃)₃ | HfP |
| Hf(NMeEt)₄ | P(SiMe₃)₃ | HfP |
| Hf(NEt₂)₄ | P(SiH₃)₃ | HfP |
| Hf(NEt₂)₄ | P(SiMe₃)₃ | HfP |
| VCl₄ | P(SiH₃)₃ | VP |
| VCl₄ | P(SiMe₃)₃ | VP |
| V(NMe₂)₄ | P(SiH₃)₃ | VP |
| V(NMe₂)₄ | P(SiMe₃)₃ | VP |
| NbCl₅ | P(SiH₃)₃ | NbP |
| NbCl₅ | P(SiMe₃)₃ | NbP |
| NbF₅ | P(SiH₃)₃ | NbP |
| NbF₅ | P(SiMe₃)₃ | NbP |
| Nb(NMe₂)₅ | P(SiH₃)₃ | NbP |
| Nb(NMe₂)₅ | P(SiMe₃)₃ | NbP |
| Nb(OEt)₅ | P(SiH₃)₃ | NbP |
| Nb(OEt)₅ | P(SiMe₃)₃ | NbP |
| TaCl₅ | P(SiH₃)₃ | TaP |
| TaCl₅ | P(SiMe₃)₃ | TaP |
| TaF₅ | P(SiH₃)₃ | TaP |
| TaF₅ | P(SiMe₃)₃ | TaP |
| Ta(NMe₂)₅ | P(SiH₃)₃ | TaP |
| Ta(NMe₂)₅ | P(SiMe₃)₃ | TaP |
| Ta(OEt)₅ | P(SiH₃)₃ | TaP |
| Ta(OEt)₅ | P(SiMe₃)₃ | TaP |
| MoCl₅ | P(SiH₃)₃ | MoP |
| MoCl₅ | P(SiMe₃)₃ | MoP |
| MoF₅ | P(SiH₃)₃ | MoP |
| MoF₅ | P(SiMe₃)₃ | MoP |
| MoO₂Cl₂ | P(SiH₃)₃ | MoP |
| MoO₂Cl₂ | P(SiMe₃)₃ | MoP |
| Mo₂(NMe₂)₆ | P(SiH₃)₃ | MoP |
| Mo₂(NMe₂)₆ | P(SiMe₃)₃ | MoP |
| Mn(N(SiMe₃)₂)₂ | P(SiH₃)₃ | MnP |
| Mn(N(SiMe₃)₂)₂ | P(SiMe₃)₃ | MnP |
| Fe₂(OtBu)₆ | P(SiH₃)₃ | FeP |
| Fe₂(OtBu)₆ | P(SiMe₃)₃ | FeP |
| CoCl₂(TMEDA) | P(SiH₃)₃ | CoP |
| CoCl₂(TMEDA) | P(SiMe₃)₃ | CoP |
| Co(N(SiMe₃)₂)₂ | P(SiH₃)₃ | CoP |
| Co(N(SiMe₃)₂)₂ | P(SiMe₃)₃ | CoP |
| Co(IPrAMD)₂ | P(SiH₃)₃ | CoP |
| Co(IPrAMD)₂ | P(SiMe₃)₃ | CoP |
| Co(acac)₂ | P(SiH₃)₃ | CoP |
| Co(acac)₂ | P(SiMe₃)₃ | CoP |
| Ni(acac)₂ | P(SiH₃)₃ | CoP |
| Ni(acac)₂ | P(SiMe₃)₃ | CoP |
| Ni(tBuAMD)₂ | P(SiH₃)₃ | CoP |
| Ni(tBuAMD)₂ | P(SiMe₃)₃ | CoP |
| Cu(acac)₂ | P(SiH₃)₃ | CuP |
| Cu(acac)₂ | P(SiMe₃)₃ | CuP |
| Cu(hfac)₂ | P(SiH₃)₃ | CuP |
| Cu(hfac)₂ | P(SiMe₃)₃ | CuP |
| CuCl | P(SiH₃)₃ | CuP |
| CuCl | P(SiMe₃)₃ | CuP |

Returning to the figures, FIG. 2 is a block diagram of example operations 200 for the deposition of metal phosphides via atomic layer deposition. The example operations 200 begin at block 202, at which a base material is positioned. For example, the base material 112 of FIG. 1 can be positioned in a wafer and die fabrication device. In some examples, the base material 112 can be a layer that was separately fabricated (e.g., a layer of a transistor, a layer of a die, etc.).

At block 204, a pulse of a metal precursor is applied to the base. For example, a pulse including the first precursor 116 of FIG. 1 can be applied (e.g., a pulse similar to the first precursor pulse 102 and/or the third precursor pulse 109 can be applied, etc.). In some examples, the pulse can be applied as a vapor and/or plasma. In other examples, the pulse of a metal precursor can be applied in any other suitable manner. At block 206, the metal precursor and the byproducts are purged. For example, the remaining metal precursor (e.g., excess metal precursor, etc.) and the byproducts (e.g., a silanide bonded to the non-metallic portion of the metal precursor, a hydrogen atom bonded to the non-metallic portion of the metal precursor, etc.) can be purged. In some examples, the metal precursor and the byproduct can be purged via an application of a purging gas (e.g., a noble gas, nitrogen gas (N₂), etc.).

At block 208, a pulse of a phosphasilane precursor is applied. For example, a pulse including the second precursor 124 of FIG. 1 can be applied (e.g., a pulse similar to the second precursor pulse 106 and/or the fourth precursor pulse 111 can be applied, etc.). In some examples, the pulse can be applied as a vapor and/or plasma. In other examples, the pulse of a phosphasilane precursor can be applied in any other suitable manner. The application of the phosphasilane precursor during the execution of block 208 after the application of the metal precursor during the execution of block 204 causes a one molecule thick layer of metal phosphide to be formed on the base material 112.

At block 210, the phosphasilane precursor and byproducts thereof are purged. For example, the remaining phosphasilane precursor (e.g., the excess phosphasilane precursor, etc.) and the byproducts (e.g., a silanide group bonded to the non-metallic portion of the metal precursor, a hydrogen bonded to the non-metallic portion of the metal precursor applied during the execution of block 204, etc.) can be purged. In some examples, the phosphasilane precursor and the byproduct can be purged via an application of a purging gas (e.g., a noble gas, nitrogen gas (N₂), etc.).

At block 212, it is determined if another layer of metal phosphide is to be deposited on the base material 112. For example, the execution of blocks 204-210 can be repeated (e.g., the alternating application of metal precursor and phosphasilane precursor, etc.) until a metal phosphide layer of a desired thickness is deposited on the base material 112. It should be appreciated that each execution of blocks 204-210 causes the thickness of the metal phosphide layer to increase in thickness by one molecule of metal phosphide (e.g., the molecular length of the metal phosphide molecule, etc.). If another metal phosphide layer is to be deposited, the operations 200 return to block 204. If another metal phosphide layer is not to be deposited, the operations 200 end.

Although the example operations 200 are described with reference to the flowchart illustrated in FIG. 2, many other methods of assembling/manufacturing for depositing a metal phosphide layer via atomic layer deposition may alternatively be used. For example, the order of execution of the blocks may be changed, and/or some of the blocks described may be changed, eliminated, or combined.

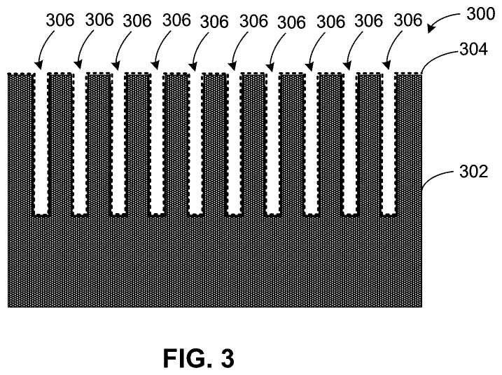

FIG. 3 is a cross-sectional view of an example apparatus 300 including an example base 302 and an example metal phosphide layer 304. In the illustrated example of FIG. 3, the base 302 includes a plurality of example high aspect ratio trenches 306. The base 302 can be any suitable component. In the illustrated example of FIG. 3, the base 302 is depicted as homogenous (e.g., composed of a single material, etc.). In other examples, the base 302 includes multiple layers of different materials. In the illustrated example of FIG. 3, the trenches 306 have a high aspect ratio (e.g., greater than 7:1, etc.).

In the illustrated example of FIG. 3, the metal phosphide layer 304 includes metal atoms (e.g., transition metal atoms, etc.) and phosphorus atoms. The metal phosphide layer 304 can be deposited by repeating the ALD cycle 100 of FIG. 1 and/or by the operations 200 of FIG. 2. In some examples, the metal phosphide layer 304 has a thickness of less than 4 nanometers. The ALD cycle 100 of the example of FIG. 1 and/or the operations 200 of FIG. 2 enable the deposition of metal phosphide layers with thicknesses as small as the length of one metal phosphide molecule. The metal phosphide layer 304 has a uniform thickness (e.g., a constant thickness, etc.) along the base 302. The application of the metal phosphide layer 304 via the ALD cycle 100 of FIG. 1 and/or the operations 200 of FIG. 2 enables the uniform application of the metal phosphide layer 304 within the trenches 306.

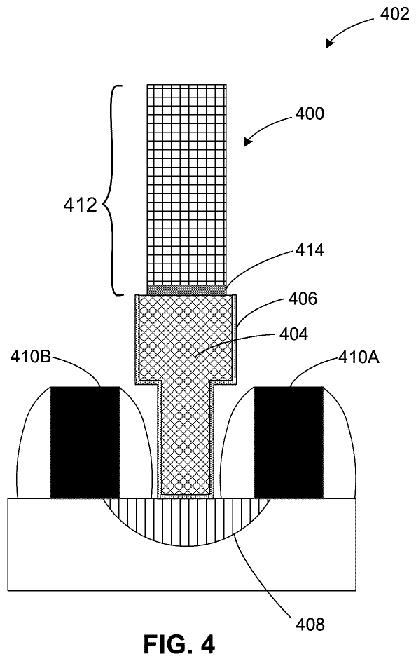

FIG. 4 is a cross-sectional schematic view of an example contact 400 of an example transistor 402 implemented in accordance with teachings of this disclosure. In the illustrated example of FIG. 4, the contact 400 includes an example main contact metal 404 and an example barrier layer 406. In the illustrated example of FIG. 4, the contact 400 is in electrical communication with an example doped silicon region 408. The doped silicon region 408 regulates the flow of current between an example first gate 410A and an example second gate 410B. In the illustrated example of FIG. 4, the barrier layer 406 is between the main contact metal 404 and the silicon region 408. During the operation of the transistor 402, a voltage can be applied via the contact 400, which changes the conductivity of the doped silicon region 408 to control the flow of current between the first gate 410A and the second gate 410B. In the illustrated example of FIG. 4, the main contact metal 404 is electrically coupled to an example contact portion 412. In some examples, the contact portion 412 is the exposed portion of the contact 400 (e.g., the portion of the transistor 402 that receives voltages to regulate flow between the gates 410A, 410B, etc.). In some examples, the contact portion 412 includes copper and/or another conductive material. In the illustrated example of FIG. 4, the contact portion 412 includes an example second barrier layer 414. In some examples, the second barrier layer 414 is a metal phosphide (e.g., includes metal atoms and phosphorus atoms, etc.). Additionally or alternatively, in some examples, the second barrier layer 414 includes tantalum (Ta), tantalum nitride (TaN), and/or cobalt (Co).

In the illustrated example of FIG. 4, the main contact metal 404 and the barrier layer 406 are depicted as integral components. In other examples, the main contact metal 404 includes multiple discrete portions that are separately coated in barrier layer(s) similar to the barrier layer 406 (e.g., including a metal phosphide, etc.). The barrier layer 406 partially coats the main contact metal 404. In some examples, the main contact metal 404 includes tungsten, molybdenum, or cobalt. In the illustrated example of FIG. 4, the barrier layer 406 is between the doped silicon region 408 (e.g., a first layer, a terminal layer, etc.) and the main contact metal 404 (e.g., a second layer, a contact layer, etc.). In some examples, the barrier layer 406 is a metal phosphide layer that includes metal atoms (e.g., transition metal atoms, etc.) and phosphorus atoms. In the illustrated example of FIG. 4, the barrier layer 406 has a uniform (e.g., constant, even, etc.) thickness along the exterior of the main contact metal 404. In some examples, the barrier layer 406 is less than or equal to 4 nanometers thick. The barrier layer 406 can be deposited by repeating the ALD cycle 100 of FIG. 1 and/or the operations 200 of FIG. 2.

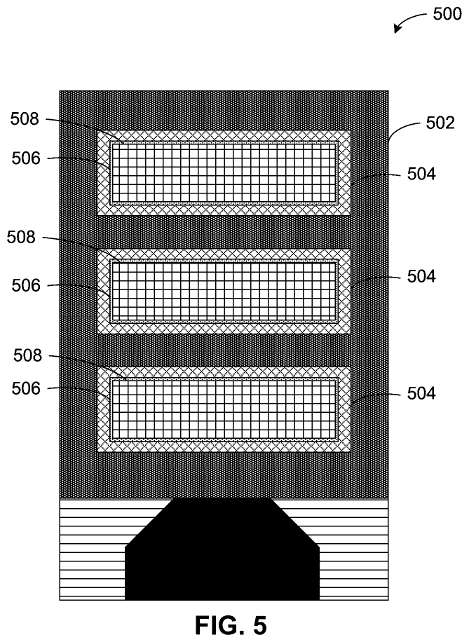

FIG. 5 is a cross-sectional schematic view of an example gate all around transistor 500 implemented in accordance with teachings of this disclosure. In the illustrated example of FIG. 5, the transistor 500 includes an example gate 502, an example plurality of dielectric layers 504, an example plurality of work function metal layers 506, and an example plurality of source layers 508. In the illustrated example of FIG. 5, each of the work function metal layers 506 is between corresponding ones of the dielectric layers 504 and the source layers 508. In the illustrated example of FIG. 5, the work function metal layers 506 are metal phosphide layers that include metal atoms (e.g., transition metal atoms, etc.) and phosphorus atoms. Metal phosphides are suitable for use as work function metal layers 506 because metal phosphides have typically highly conductive (e.g., have a low resistance, etc.) and corrosion-resistant (e.g., comparatively low reactivity with oxygen and water, etc.). Additionally, different metal phosphides can be utilized to tune the work function of the transistor 500 (e.g., electronegative metal phosphides (e.g., TiP, ScP, MoP, etc.), electropositive metal phosphides (e.g., NiP, CoP, etc.). The p-work function metal layers 506 can be deposited by repeating the ALD cycle 100 of FIG. 1 and/or the operations 200 of FIG. 2. In some examples, the p-work function metal layers 506 have a thickness of less than 4 nanometers.

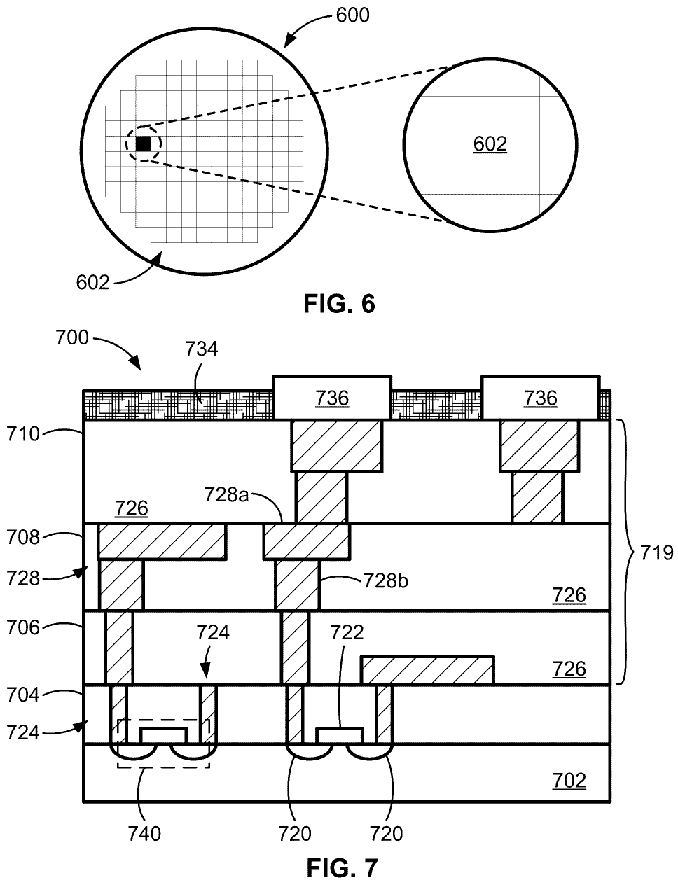

FIG. 6 is a top view of a wafer 600 and dies 602 that may be included in the apparatus 300 of FIG. 3, the transistor 402 of FIG. 4, and/or the transistor 500 of FIG. 5. The wafer 600 includes semiconductor material and one or more dies 602 having IC structures formed on a surface of the wafer 600. Each of the dies 602 may be a repeating unit of a semiconductor product that includes any suitable IC. After the fabrication of the semiconductor product is complete, the wafer 600 may undergo a singulation process in which the dies 602 are separated from one another to provide discrete “chips” of the semiconductor product. The die 602 may include one or more transistors (e.g., some of the transistors 740 of FIG. 7, discussed below), supporting circuitry to route electrical signals to the transistors, passive components (e.g., signal traces, resistors, capacitors, or inductors), and/or any other IC components. In some examples, the wafer 600 or the die 602 includes a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 602. For example, a memory array of multiple memory devices may be formed on a same die 602 as processor circuitry and/or other circuitry that is configured to store information in the memory devices and/or execute instructions stored in the memory array. The example apparatus 300 of FIG. 3, the transistor 402 of FIG. 4, and/or the transistor 500 of FIG. 5 disclosed herein may be manufactured using a die-to-wafer assembly technique in which some dies are attached to a wafer 600, and the wafer 600 is subsequently singulated.

FIG. 7 is a cross-sectional side view of an IC device 700 that may be included in the example the apparatus 300 of FIG. 3, the transistor 402 of FIG. 4, and/or the transistor 500 of FIG. 5. One or more of the IC devices 700 may be included in one or more dies 602 (FIG. 6). The IC device 700 may be formed on a die substrate 702 (e.g., the wafer 600 of FIG. 6) and may be included in a die (e.g., the die 602 of FIG. 6). The die substrate 702 may be a semiconductor substrate including semiconductor material including, for example, n-type or p-type materials systems (or a combination of both). The die substrate 702 may include, for example, a crystalline substrate formed using a bulk silicon or a silicon-on-insulator (SOI) substructure. In some examples, the die substrate 702 may be formed using alternative materials, which may or may not be combined with silicon, which include but are not limited to germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an IC device 700 may be used. The die substrate 702 may be part of a singulated die (e.g., the dies 602 of FIG. 6) or a wafer (e.g., the wafer 600 of FIG. 6).

The IC device 700 may include one or more device layers 704 on and/or above the die substrate 702. The device layer 704 may include features of one or more transistors 740 (e.g., metal oxide semiconductor field-effect transistors (MOSFETs)) formed on the die substrate 702. The device layer 704 may include, for example, one or more source and/or drain (S/D) regions 720, a gate 722 to control current flow in the transistors 740 between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 740 may include a gate 722 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 740 along the source-channel-drain direction, the gate electrode may include a U-shaped structure that includes a bottom portion substantially parallel to the surface of the die substrate 702 and two sidewall portions that are substantially perpendicular to the top surface of the die substrate 702. In other examples, at least one of the metal layers that form the gate electrode may be a planar layer that is substantially parallel to the top surface of the die substrate 702 and does not include sidewall portions substantially perpendicular to the top surface of the die substrate 702. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of corresponding transistor(s) 740. The S/D regions 720 may be formed using an implantation/diffusion process or an etching/deposition process, for example. In the former process, dopants such as boron, aluminum, antimony, phosphorus, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some examples, the epitaxially deposited silicon alloy may be doped in situ with dopants such as boron, arsenic, or phosphorus. In some examples, the S/D regions 720 may be formed using one or more alternate semiconductor materials such as germanium or a group III-V material or alloy. In further examples, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the IC device 700.

The interconnect structures 728 may be arranged within the interconnect layers 706-710 to route electrical signals according to a wide variety of designs (in particular, the arrangement is not limited to the particular configuration of interconnect structures 728 depicted in FIG. 7). Although a particular number of interconnect layers 706-710 is depicted in FIG. 7, examples of the present disclosure include IC devices having more or fewer interconnect layers than depicted.

In some examples, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and/or out of the page from the perspective of FIG. 7. The vias 728b may be arranged to route electrical signals in a direction of a plane that is substantially perpendicular to the surface of the die substrate 702 upon which the device layer 704 is formed. In some examples, the vias 728b may electrically couple lines 728a of different interconnect layers 706-710 together.

The interconnect layers 706-710 may include a dielectric material 726 disposed between the interconnect structures 728, as shown in FIG. 7. In some examples, the dielectric material 726 disposed between the interconnect structures 728 in different ones of the interconnect layers 706-710 may have different compositions; in other examples, the composition of the dielectric material 726 between different interconnect layers 706-710 may be the same.

A first interconnect layer 706 (referred to as Metal 1 or “M1”) may be formed directly on the device layer 704. In some examples, the first interconnect layer 706 may include lines 728a and/or vias 728b, as shown. The lines 728a of the first interconnect layer 706 may be coupled with contacts (e.g., the S/D contacts 724) of the device layer 704.

A second interconnect layer 708 (referred to as Metal 2 or “M2”) may be formed directly on the first interconnect layer 706. In some examples, the second interconnect layer 708 may include vias 728b to couple the lines 728a of the second interconnect layer 708 with the lines 728a of the first interconnect layer 706. Although the lines 728a and the vias 728b are structurally delineated with a line within each interconnect layer (e.g., within the second interconnect layer 708) for the sake of clarity, the lines 728a and the vias 728b may be structurally and/or materially contiguous (e.g., simultaneously filled during a dual-damascene process) in some examples.

A third interconnect layer 710 (referred to as Metal 3 or “M3”) (and additional interconnect layers, as desired) may be formed in succession on the second interconnect layer 708 according to similar techniques and/or configurations described in connection with the second interconnect layer 708 or the first interconnect layer 706. In some examples, the interconnect layers that are “higher up” in the metallization stack 719 in the IC device 700 (i.e., further away from the device layer 704) may be thicker.

The IC device 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to other external devices. For example, solder bonds may be formed on the one or more conductive contacts 736 to mechanically and/or electrically couple a chip including the IC device 700 with another component (e.g., a circuit board). The IC device 700 may include additional or alternate structures to route the electrical signals from the interconnect layers 706-710; for example, the conductive contacts 736 may include other analogous features (e.g., posts) that route the electrical signals to external components.

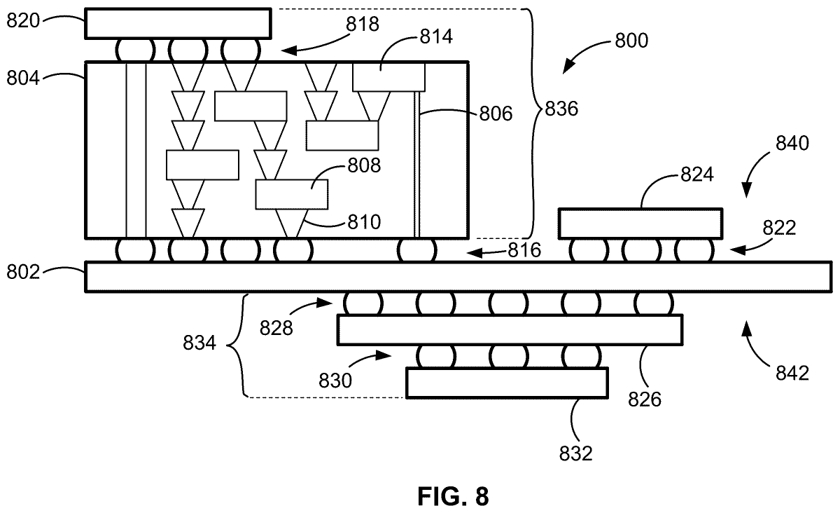

FIG. 8 is a cross-sectional side view of an IC device assembly 800 that may include the apparatus 300 of FIG. 3, the transistor 402 of FIG. 4, and/or the transistor 500 of FIG. 5 disclosed herein. In some examples, the IC device assembly corresponds to the apparatus 300 of FIG. 3, the transistor 402 of FIG. 4, and/or the transistor 500 of FIG. 5. The IC device assembly 800 includes a number of components disposed on a circuit board 802 (which may be, for example, a motherboard). The IC device assembly 800 includes components disposed on a first face 840 of the circuit board 802 and an opposing second face 842 of the circuit board 802; generally, components may be disposed on one or both faces 840 and 842. Any of the IC packages discussed below with reference to the IC device assembly 800 may take the form of the example the apparatus 300 of FIG. 3, the transistor 402 of FIG. 4, and/or the transistor 500 of FIG. 5 of FIG. 5.

In some examples, the circuit board 802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 802. In other examples, the circuit board 802 may be a non-PCB substrate.

The IC device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), male and female portions of a socket, an adhesive, an underfill material, and/or any other suitable electrical and/or mechanical coupling structure.

The package-on-interposer structure 836 may include an IC package 820 coupled to an interposer 804 by coupling components 818. The coupling components 818 may take any suitable form for the application, such as the forms discussed above with reference to the coupling components 816. Although a single IC package 820 is shown in FIG. 8, multiple IC packages may be coupled to the interposer 804; indeed, additional interposers may be coupled to the interposer 804. The interposer 804 may provide an intervening substrate used to bridge the circuit board 802 and the IC package 820. The IC package 820 may be or include, for example, a die (the die substrate 702 of FIG. 7), an IC device (e.g., the IC device 800 of FIG. 8), or any other suitable component. Generally, the interposer 804 may spread a connection to a wider pitch or reroute a connection to a different connection. For example, the interposer 804 may couple the IC package 820 (e.g., a die) to a set of BGA conductive contacts of the coupling components 816 for coupling to the circuit board 802. In the example illustrated in FIG. 8, the IC package 820 and the circuit board 802 are attached to opposing sides of the interposer 804; in other examples, the IC package 820 and the circuit board 802 may be attached to a same side of the interposer 804. In some examples, three or more components may be interconnected by way of the interposer 804.

In some examples, the interposer 804 may be formed as a PCB, including multiple metal layers separated from one another by layers of dielectric material and interconnected by electrically conductive vias. In some examples, the interposer 804 may be formed of an epoxy resin, a fiberglass-reinforced epoxy resin, an epoxy resin with inorganic fillers, a ceramic material, or a polymer material such as polyimide. In some examples, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias 810, including but not limited to through-silicon vias (TSVs) 806. The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art.

The IC device assembly 800 may include an IC package 824 coupled to the first face 840 of the circuit board 802 by coupling components 822. The coupling components 822 may take the form of any of the examples discussed above with reference to the coupling components 816, and the IC package 824 may take the form of any of the examples discussed above with reference to the IC package 820.

The IC device assembly 800 illustrated in FIG. 8 includes a package-on-package structure 834 coupled to the second face 842 of the circuit board 802 by coupling components 828. The package-on-package structure 834 may include a first IC package 826 and a second IC package 832 coupled together by coupling components 830 such that the first IC package 826 is disposed between the circuit board 802 and the second IC package 832. The coupling components 828, 830 may take the form of any of the examples of the coupling components 816 discussed above, and the IC packages 826, 832 may take the form of any of the examples of the IC package 820 discussed above. The package-on-package structure 834 may be configured in accordance with any of the package-on-package structures known in the art.

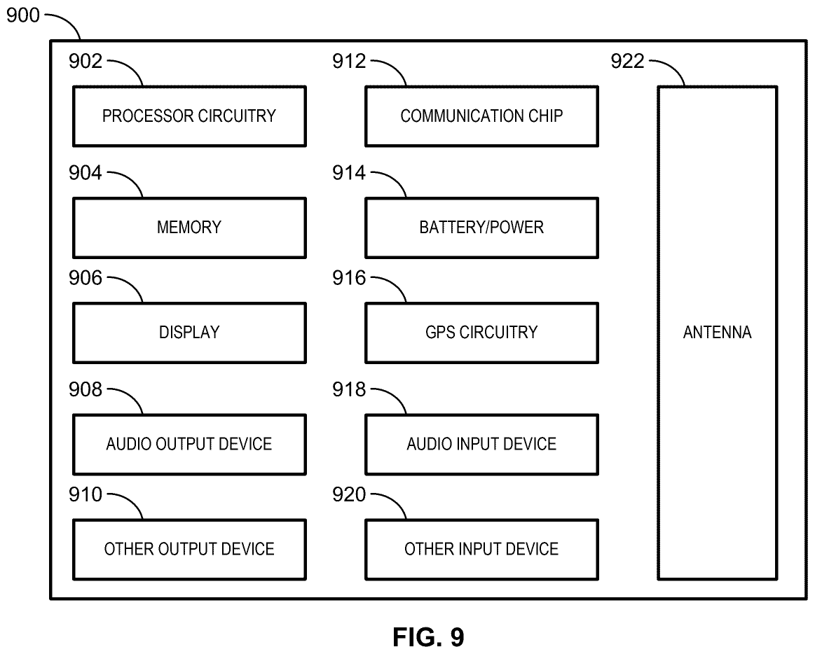

FIG. 9 is a block diagram of an example electrical device 900 that may include one or more of the example the apparatus 300 of FIG. 3, the transistor 402 of FIG. 4, and/or the transistor 500 of FIG. 5 of FIGS. 2, 3, 5, and 15. For example, any suitable ones of the components of the electrical device 900 may include one or more of the device assemblies 900, IC devices 800, or die substrate 702 disclosed herein, and may be arranged in the example the apparatus 300 of FIG. 3, the transistor 402 of FIG. 4, and/or the transistor 500 of FIG. 5. A number of components are illustrated in FIG. 9 as included in the electrical device 900, but any one or more of these components may be omitted or duplicated, as suitable for the application. In some examples, some or all of the components included in the electrical device 900 may be attached to one or more motherboards. In some examples, some or all of these components are fabricated onto a single system-on-a-chip (SoC) die.

Additionally, in various examples, the electrical device 900 may not include one or more of the components illustrated in FIG. 9, but the electrical device 900 may include interface circuitry for coupling to the one or more components. For example, the electrical device 900 may not include a display 906, but may include display interface circuitry (e.g., a connector and driver circuitry) to which a display 906 may be coupled. In another set of examples, the electrical device 900 may not include an audio input device 918 (e.g., microphone) or an audio output device 908 (e.g., a speaker, a headset, earbuds, etc.), but may include audio input or output device interface circuitry (e.g., connectors and supporting circuitry) to which an audio input device 918 or audio output device 908 may be coupled.

The electrical device 900 may include a processor circuitry 902 (e.g., one or more processing devices). As used herein, the term “processing device” or “processor” may refer to any device or portion of a device that processes electronic data from registers and/or memory to transform that electronic data into other electronic data that may be stored in registers and/or memory. The processor circuitry 902 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 900 may include a memory 904, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 904 may include memory that shares a die with the processor circuitry 902. This memory may be used as cache memory and may include embedded dynamic random access memory (eDRAM) or spin transfer torque magnetic random access memory (STT-MRAM).

In some examples, the electrical device 900 may include a communication chip 912 (e.g., one or more communication chips). For example, the communication chip 912 may be configured for managing wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2505 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 912 may operate in accordance with other wireless protocols in other examples. The electrical device 900 may include an antenna 922 to facilitate wireless communications and/or to receive other wireless communications (such as AM or FM radio transmissions).

In some examples, the communication chip 912 may manage wired communications, such as electrical, optical, or any other suitable communication protocols (e.g., the Ethernet). As noted above, the communication chip 912 may include multiple communication chips. For instance, a first communication chip 912 may be dedicated to shorter-range wireless communications such as Wi-Fi or Bluetooth, and a second communication chip 912 may be dedicated to longer-range wireless communications such as global positioning system (GPS), EDGE, GPRS, CDMA, WiMAX, LTE, EV-DO, or others. In some examples, a first communication chip 912 may be dedicated to wireless communications, and a second communication chip 912 may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display 906 (or corresponding interface circuitry, as discussed above). The display 906 may include any visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any device that generates an audible indicator, such as speakers, headsets, or earbuds.

The electrical device 900 may include an audio input device 918 (or corresponding interface circuitry, as discussed above). The audio input device 918 may include any device that generates a signal representative of a sound, such as microphones, microphone arrays, or digital instruments (e.g., instruments having a musical instrument digital interface (MIDI) output).

The electrical device 900 may include GPS circuitry 916. The GPS circuitry 916 may be in communication with a satellite-based system and may receive a location of the electrical device 900, as known in the art.

The electrical device 900 may include any other output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include any other input device 920 (or corresponding interface circuitry, as discussed above). Examples of the other input device 920 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 900 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor component (e.g., a transistor), a semiconductor die containing a semiconductor component, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor component) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor components are often used in orientation different than their orientation during fabrication. Thus, when referring to a semiconductor component (e.g., a transistor), a semiconductor die containing a semiconductor component, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

Example 1 includes an integrated circuitry (IC) package including a substrate, and a transistor including a first layer, a second layer, and a third layer between the first layer and second layer, the third layer including a metal and a phosphide, the third layer having a thickness of less than 4 nanometers.

Example 2 includes the integrated circuitry (IC) package of any preceding example, wherein the transistor is a gate all around transistor.

Example 3 includes the integrated circuitry (IC) package of any preceding example, wherein the first layer is a channel layer, the second layer is a dielectric layer, and the third layer is a p-work function metal layer.

Example 4 includes the integrated circuitry (IC) package of any preceding example, wherein the transistor is a metal-oxide-semiconductor field-effect transistors.

Example 5 includes the integrated circuitry (IC) package of any preceding example, wherein the first layer is a terminal layer, the second layer is a contact layer, and the third layer is a barrier layer.

Example 6 includes the integrated circuitry (IC) package of any preceding example, wherein the metal phosphide includes a transition metal.

Example 7 includes an apparatus including a first layer, a second layer, and a third layer between the first layer and second layer, the third layer including a metal and a phosphide, the third layer having a thickness of less than 4 nanometers.

Example 8 includes the apparatus of any preceding example, wherein the metal phosphide includes a transition metal.

Example 9 includes the apparatus of any preceding example, wherein the first layer is a channel layer, the second layer is a dielectric layer, and the third layer is a p-work metal layer.

Example 10 includes the apparatus of any preceding example, wherein the first layer is a terminal layer, the second layer is a contact layer, and the third layer is a barrier layer.

Example 11 includes the apparatus of any preceding example, wherein the first layer includes a trench having an aspect ratio of at least 7:1, the second layer having a uniform thickness in the trench.

Example 12 includes a method to deposit a metal phosphide layer via atomic layer deposition, the method including applying a first pulse of a metal precursor to a substrate, purging the first pulse, applying a second pulse of a phosphasilane precursor, and purging the second pulse.

Example 13 includes the method of any preceding example, wherein the phosphasilane precursor includes trisilylphosphine.

Example 14 includes the method of any preceding example, wherein the phosphasilane precursor includes Tris(trimethylsilyl)-phosphine.

Example 15 includes the method of any preceding example, wherein the phosphasilane precursor is applied as a gas.

Example 16 includes the method of any preceding example, wherein the metal precursor includes a metal chloride.

Example 17 includes the method of any preceding example, wherein the metal precursor includes a metal fluoride.

Example 18 includes the method of any preceding example, wherein the metal precursor includes a metal amide.

Example 19 includes the method of any preceding example, wherein the metal precursor includes a metal alkoxide.

Example 20 includes the method of any preceding example, wherein the metal precursor includes a transition metal.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An integrated circuitry (IC) package including:
a substrate; and
a transistor including:
a first layer;
a second layer; and
a third layer between the first layer and second layer, the third layer including a metal and a phosphide, the third layer having a thickness of less than 4 nanometers.

2. The integrated circuitry (IC) package of claim 1, wherein the transistor is a gate all around transistor.

3. The integrated circuitry (IC) package of claim 2, wherein the first layer is a channel layer, the second layer is a dielectric layer, and the third layer is a p-work function metal layer.

4. The integrated circuitry (IC) package of claim 1, wherein the transistor is a metal-oxide-semiconductor field-effect transistors.

5. The integrated circuitry (IC) package of claim 4, wherein the first layer is a terminal layer, the second layer is a contact layer, and the third layer is a barrier layer.

6. The integrated circuitry (IC) package of claim 1, wherein the metal phosphide includes a transition metal.

7. An apparatus including:
a first layer;
a second layer; and
a third layer between the first layer and second layer, the third layer including a metal and a phosphide, the third layer having a thickness of less than 4 nanometers.

8. The apparatus of claim 7, wherein the metal phosphide includes a transition metal.

9. The apparatus of claim 7, wherein the first layer is a channel layer, the second layer is a dielectric layer, and the third layer is a p-work metal layer.

10. The apparatus of claim 9, wherein the first layer is a terminal layer, the second layer is a contact layer, and the third layer is a barrier layer.

11. The apparatus of claim 7, wherein the first layer includes a trench having an aspect ratio of at least 7:1, the second layer having a uniform thickness in the trench.

12. A method to deposit a metal phosphide layer via atomic layer deposition, the method including:
applying a first pulse of a metal precursor to a substrate;
purging the first pulse;
applying a second pulse of a phosphasilane precursor; and
purging the second pulse.

13. The method of claim 12, wherein the phosphasilane precursor includes trisilylphosphine.

14. The method of claim 12, wherein the phosphasilane precursor includes Tris(trimethylsilyl)-phosphine.

15. The method of claim 12, wherein the phosphasilane precursor is applied as a gas.

16. The method of claim 12, wherein the metal precursor includes a metal chloride.

17. The method of claim 12, wherein the metal precursor includes a metal fluoride.

18. The method of claim 12, wherein the metal precursor includes a metal amide.

19. The method of claim 12, wherein the metal precursor includes a metal alkoxide.

20. The method of claim 12, wherein the metal precursor includes a transition metal.
